(19) United States
(12) Patent Application Publication
(10) Pub. No.: US 2013/0000723 A1
(43) Pub. Date: Jan. 3, 2013

(54) PHOTOCHEMICAL ELECTRODE, CONSTRUCTION AND USES THEREOF

(75) Inventors: Itamar Willner, Mevasseret Zion (IL); Rachel Nechushtal, Motza I'llit (IL); Ran Tel-Vered, Jerusalem (IL); Omer Yehezkeli, Jerusalem (IL); Ofer Israel Willner, Tel Aviv (IL); Dan Roizman-Sade, Hadera (IL)

(73) Assignee: Yissum Research Development Company of the Hebrew Unversity of Jerusalem Ltd, Jerusalem (IL)

(21) Appl. No.: 13/635,146

(22) PCT Filed: Mar. 24, 2011
(86) PCT No.: PCT/IL11/00273

§ 371 Date: Sep. 14, 2012

Related U.S. Application Data
(60) Provisional application No. 61/317,469, filed on Mar. 25, 2010.

(51) Int. Cl. H01L 31/0224; C25D 15/00

(52) U.S. Cl. 136/256; 205/109

(57) ABSTRACT

The present invention provides an electrode comprising a conductive surface connected to a composite matrix of at least one noble metal nano-particle, at least one photo-catalytic element and at least one connecting group, photovoltaic cells and devices comprising said electrode and processes for preparing said electrode.

### FIELD OF THE INVENTION

This invention relates to electrodes comprising composites and processes for their preparation. The invention further relates to methods and systems for generating photochemical currents.

### BACKGROUND OF THE INVENTION

The development of dye-photosensitized solar cells has progressed in the last three decades especially with respect to the improvement of the energy conversion efficiency [1-5].

Photo-system I (PSI) is a complex protein existing in plants, algae, and cyanobacteria [6] and it functions in the reducing site/end of the photosynthetic machinery [7]. PSI consists of a collection of chlorophylls that harvest the incident photons and funnel the light energy to the photosynthetic reaction center, where electron transfer and charge separation occur. The uniqueness of the photosynthetic reaction center, P700, resets on the fact that the spatial organization of both the photosensitizing units and the electron relays in the electron transfer chain leads to a quantum efficiency of unity [8]. The structure of the PSI was elucidated, revealing the positions of the different relay units and cofactors as well as their functions in the electron transfer cascade [9-11]. The integration of PSI with an electrode of the invention transfers the unique photoinduced charge separation features of the biomaterial into electrical power.

Previous studies reported assemblies of PSI on solid supports and applications of PSI in photoelectrochemical systems [24-27], including PSI-based devices [28-33]. The photocurrents generated by the different PSI systems were usually low, and only integrated photocurrent values resulting upon irradiation with the entire visible spectrum were reported without recording the photocurrent action spectra under monochromatic irradiation.

Development of improved light harvesting systems that will overlap the entire solar spectrum and will yield an effective charge separation of photoexcited electron-hole pairs is therefore needed.

The present invention discloses chemical modification of PSI into an electropolymerizable material which yielded effective photocurrent-generating electrodes.

The following publications are considered relevant for describing the state of the art in the field of the invention:
[1] Kamat, P. V. J. Phys. Chem. C 2007, 111, 2834.
[2] Kamat, P. V. Chem. Rev. 1993, 93, 267.
[3] Gratzel, M. Nature 2001, 414, 338.
[4] Wang, P.; Zakeeruddin, S. M.; Comte, P.; Exnar, I.; Gratzel, M. J. Am. Chem. Soc. 2003, 125, 1166.
[5] Brown, P.; Takechi, K.; Kamat, P. V. J. Phys. Chem. C 2008, 112, 4776.
[6] Chitnis, P. R. Annu. Rev. Plant. Physiol. Plant. Mol. Biol. 2001, 52, 593.
[7] Nelson, N.; Ben-Shem, A. Nat. Rev. Mol. Cell. Biol. 2004, 5, 971.
[8] Brettel, K.; Leibl, W. Biochim. Biophys. Acta, Bioenerg. 2001, 1507, 100.
[9] Jordan, P.; Fromme, P.; Witt, H. T.; Klukas, O.; Saenger, W.; Krauss, N. Nature 2001, 411, 909.
[10] Munge, B.; Das, S. K.; Hagan, R.; Pendon, Z.; Yang, J.; Frank, H. A.; Rusling, J. F. J. Am. Chem. Soc. 2003, 125, 12457.
[11] Iwaki, M.; Itoh, S. FEBS Lett. 1989, 256, 11.
[12] Willner, I.; Willner, B. Trends Biotechnol. 2001, 19, 222.
[13] Xiao, Y.; Lubin, A. A.; Baker, B. R.; Plaxco, K. W.; Heeger, A. J. PNAS 2006, 103, 16677.
[14] Xiao, Y.; Lubin, A. A.; Heeger, A. J.; Plaxco, K. W. Angew. Chem. Int. Ed. 2005, 44, 5456.
[15] Chen, T.; Barton, S. C.; Binyamin, G.; Gao, Z. Q.; Zhang, Y. C.; Kim, H. H.; Heller, A. J. Am. Chem. Soc. 2001, 123, 8630.
[16] Drummond, T. G.; Hill, M. G.; Barton, J. K. Nat. Biotechnol. 2003, 21, 1192.
[17] Willner, I. Science 2002, 298, 2407.
[18] Medintz, I. L.; Konnert, J. H.; Clapp, A. R.; Stanish, I.; Twigg, M. E.; Mattoussi, H.; Mauro, J. M.; Deschamps, J. R. PNAS 2004, 101, 9612.
[19] Niemeyer, C. M. Angew. Chem. Int. Ed. 2001, 40, 4128.
[20] d'Ischia, M.; Napolitano, A.; Pezzella, A.; Meredith, P.; Sarna, T. Angew. Chem. Int. Ed. 2009, 48, 3914.
[21] Jin, Y. D.; Friedman, N.; Sheves, M.; Cahen, D. Adv. Fund. Mater. 2007, 17, 1417.
[22] Willner, I. Acc. Chem. Res. 1997, 30, 347.
[23] Esper, B.; Badura, A.; Rogner, M. Trends Plant Sci. 2006, 11, 543.
[24] Frolov, L.; Rosenwaks, Y.; Carmeli, C.; Carmeli, I. Adv. Mater. 2005, 17, 2434.
[25] Frolov, L.; Wilner, O.; Carmeli, C.; Carmeli, I. Adv. Mater. 2008, 20, 263.
[26] Greenbaum, E. Science 1985, 230, 1373.
[27] Lee, J. W.; Lee, I.; Greenbaum, E. Biosens. Bioelectron. 1996, 11, 375.
[28] Das, R.; Kiley, P. J.; Segal, M.; Norville, J.; Yu, A. A.; Wang, L. Y.; Trammell, S. A.; Reddick, L. E.; Kumar, R.; Stellacci, F.; Lebedev, N.; Schnur, J.; Bruce, B. D.; Zhang, S. G.; Baldo, M. Nano Lett. 2004, 4, 1079.
[29] Carmeli, I.; Mangold, M.; Frolov, L.; Zebli, B.; Carmeli, C.; Richter, S.; Holleitner, A. W. Adv. Mater. 2007, 19, 3901.
[30] Terasaki, N.; Yamamoto, N.; Hiraga, T.; Sato, I.; Inoue, Y.; Yamada, S. Thin Solid Films 2006, 499, 153.
[31] Ciesielski, P. N.; Scott, A. M.; Faulkner, C. J.; Berron, B. J.; Cliffel, D. E.; Jennings, G. K. ACS Nano 2008, 2, 2465.
[32] Terasaki, N.; Yamamoto, N.; Hiraga, T.; Yamanoi, Y.; Yonezawa, T.; Nishihara, H.; Ohmori, T.; Sakai, M.; Fujii, M.; Tohri, A.; Iwai, M.; Inoue, Y.; Yoneyama, S.; Minakata, M.; Enami, I. Angew. Chem. Int. Ed. 2009, 48, 1585.
[33] Grimme, R. A.; Lubner, C. E.; Bryant, D. A.; Golbeck, J. H. J. Am. Chem. Soc. 2008, 130, 6308.
[34] Yehezkeli, O.; Wilner O. I.; Tel-Vered, R.; Roizman-Sade, D.; Nechushtai, R.; Willner, I. J. Phys. Chem. B 2010, 114, 14383.
[35] Bahshi, L.; Frasconi, M.; Tel-Vered, R.; Yehezkeli, O.; Willner, I. Anal. Chem. 2008, 80, 8253.
[36] Yehezkeli, O.; Yan, Y. M.; Baravik, I.; Tel-Vered, R.; Willner, I. Chem. Eur. J. 2009, 15, 2674.
[37] Willner, I.; Yan, Y. M.; Willner, B.; Tel-Vered, R. Fuel Cells 2009, 9, 7.
[38] Yildiz, H. B.; Tel-Vered, R.; Willner, I. Adv. Fund. Mater. 2008, 18, 3497.
[39] Zayats, M.; Katz, E.; Baron, R.; Willner, I. J. Am. Chem. Soc. 2005, 127, 12400.
[40] Xiao, Y.; Patolsky, F.; Katz, E.; Hainfeld, J. F.; Willner, I. Science 2003, 299, 1877.
[41] Germano, M.; Yakushevska, A. E.; Keegstra, W.; van Gorkom, H. J.; Dekker, J. P.; Boekema, E. J. FEBS Lett 2002, 525, 121.
[42] Setif, P.; Fischer, N.; Lagoutte, B.; Bottin, H.; Rochaix, J. D. Biochim. Biophys. Acta, Bioenerg. 2002, 1555, 204.

[43] Nechushtai, R.; Muster, P.; Binder, A.; Liveanu, V.; Nelson, N. Proc. Nat. Acad. Sci. U.S.A. 1983, 80, 1179.

### SUMMARY OF THE INVENTION

The present invention provides electrodes useful for generating a photocurrent and devices comprising them.

In one aspect of the present invention, there is provided an electrode comprising a conductive surface connected to a composite matrix;

said matrix comprising: (i) at least one noble metal nano-particle, (ii) at least one photo-catalytic element and (iii) at least one connecting group said composite matrix being capable of transferring electrons from or to said surface upon exposure to light.

In some embodiments said at least one connecting group links said at least one nano-particle and at least one photo-catalytic element (i.e. matrix components) to one another (i.e. matrix connecting group). In another embodiment said at least one connecting group links the composite matrix to the conductive surface (i.e. surface connecting group). In a further embodiment said electrode of the invention comprises at least one matrix connecting group and at least one surface connecting group, which may be the same or different.

In another one of its aspects the invention provides an electrode comprising a conductive surface connected to a composite matrix; said matrix comprising: noble metal nanoparticles, photocatalytic elements and connecting groups linking matrix components to one another and linking the matrix to the conductive surface; said matrix being capable of transferring electrons from or to said surface upon exposure to light.

In another aspect of the invention, there is provided an electrode comprising a conductive surface connected to a composite matrix; said composite matrix comprising a plurality of noble metal nano-particles and a plurality of photo-catalytic elements; wherein:
substantially each nano-particle of said plurality of nano-particles is connected by at least one type of composite connecting group to at least one of: (i) at least one other nano-particle of the composite and (ii) at least one photo-catalytic element; and
at least a portion of said plurality of nano-particles is connected to said conductive surface by at least one surface connecting group.

In some embodiments, said composite connecting group and surface connecting group, may be the same or different. In other embodiments, composite connecting group connecting NPs to one another may be the same or different than a composite connecting group connecting NP to photo-catalytic element, or may be the same or different than a composite connecting group connecting photo-catalytic elements to one another.

The term “electrode” as used herein should be understood to encompass a device with an electrically conducting assembly. This assembly, in accordance with the invention, comprises a composite matrix having a plurality of noble metal nano-particles (NPs) and a plurality photo-catalytic elements connected to one another and to the conductive surface, via connecting groups which may be the same or different. Electrodes of the invention are light sensitive electrodes capable of transforming photonic energy into electrical energy, employing photo-electrochemical processes.

A conductive surface employed by an electrode of the invention may be any conductive metal surface such as for example gold, platinum, silver, suitable alloys, etc or any alloy or combination thereof. The conductive surface of the invention may also be made of conductive materials other than pure metal such as, for example graphite, Indium-Tin-Oxide (ITO), etc. The electrical responsiveness of the electrode depends, among others, on the surface area of the conducting surface. According to some embodiments the surface area is increased by roughening or the use of a porous surface. It should be noted that through such increase in specific surface area the overall size or dimensions of the electrode may be decreased. A conductive surface employed by an electrode of the invention may be in any shape or form, such as for example in a flat, sheet like structure or as a three dimensional body having a top, bottom and side faces which may all or partially be conductive.

A composite matrix structure as described herein above and below, connected to said conductive surface of an electrode of the invention comprises a plurality of at least one type of photo-catalytic element and a plurality of at least one type noble metal NPs.

In some embodiments, substantially each of said NPs and photo-catalytic elements of said matrix are connected to one another or to the conductive surface of an electrode of the invention, through at least one type of connecting group. In other embodiments, at least one type of connecting group connects NPs to one another. In other embodiments at least one type of connecting group connects photo-catalytic elements to one another. In yet further embodiments, at least one type of connecting group connects a photo-catalytic element to a NP of the matrix. In yet further embodiments, at least one type of connecting group connects NPs to the conductive surface of the electrode. In yet further embodiments, at least one type of connecting group connects photo-catalytic element to the conductive surface of an electrode. In other embodiments, at least two photo-catalytic elements in a matrix of an electrode of the invention may be connected directly to one another.

The composite matrix components described above may be structured in any two or three dimensional form structure. It should be understood that the components of the matrix may be formed in an ordered, non-ordered or amorfic forms. In some embodiments said matrix components may form a monolayer on said conductive surface (i.e. a monolayer of a connecting group is connected to a monolayer of NP connected either directly or via another, same or different, connecting group to a photo-catalytic element, e.g. PSII). In some embodiments a composite matrix of an electrode of the invention comprising a plurality of photo-catalytic elements and noble metal nano-particles; wherein substantially each photo-catalytic element of said plurality of complexes is connected to at least one noble metal nano-particle by at least one connecting group in a heterogeneous, non-ordered structure (wherein no layer of a single type of nano-particle is formed). The matrix structure may be constructed through electrochemical processes involving the components of the matrix, such as electropolymerization processes.

The composite matrix is associated with the conductive surface by connecting groups, which may be the same or different than the connecting groups connecting between the matrix components of an electrode of the invention. In some embodiments, the association of the composite matrix to the conductive surface may be achieved through the use of electrochemical processes indicated above. In one embodiment said matrix is fabricated in situ on said conductive surface, using electropolymerization processes, thereby forming an electrode of the invention.

The term “a plurality of noble metal nano particles and photo-catalytic elements” should be understood to encompass any combination of noble metal nano-particles and photo-catalytic elements. The noble metal nano-particles may comprise at least one type of nano-particles of a noble metal substance. Similarly, the photocatalytic element may comprise at least one type of photo-catalytic elements. In another embodiment the matrix may comprise two or more types (species) of photo-catalytic elements and/or two or more types of noble metal nano-particles.

As used herein the term “nano-particles” (NPs) refers to any particle for which at least one dimension of the particles (diameter, width) has a size in the range of about 1 nm to 200 nm. The term also refers to particles having any shape such as spherical, elongated, cylindrical, or to amorphous nano-particles. In case two or more types of noble metal nano-particles construct the matrix of an electrode of the invention, each type may have the same or different size and/or shape.

The term “photo-catalytic element” refers to a complex of at least one polypeptide and other small molecules (e.g. chlorophyll and pigment molecules), which when integrated together work as a functional unit converting light energy to chemical energy. Typically the photo-catalytic elements employed by an electrode of the present invention are present in photosynthetic organisms (i.e. organisms that convert light energy into chemical energy). Non-limiting examples of photosynthetic organisms include, green plants, cyanobacteria, red algae, purple and green bacteria.

Thus, examples of photo-catalytic elements which can be used in accordance with this aspect of the present invention include biological photo-catalytic units such as PS I and PS II, bacterial light-harvesting proteins e,g, bacteriorhodopsin or bacterial reaction centers, photo-catalytic microorganisms, pigments (e.g., proflavine and rhodopsin, chlorophylls), and algal light harvesting compelexes like PSI, PSII or Light Harvesting Complexes. A photo-catalytic element can also refer to isolated components of naturally occurring photosystem such as PSI and PSII and bacterial-RC. It should be noted that the elements, or their components may be naturally occurring or systemically produced, using for example, various genetically engineering techniques.

In some embodiments, a photo-catalytic element of the present invention is a photosystem complex.

The term “photosystem complex” as used herein is meant to encompass a protein complex involved in photosynthesis. Such complexes may be isolated from the thylakoid membranes of plants, algae and cyanobacteria (in plants and algae these are located in the chloroplasts), or in the cytoplasmic membrane of photosynthetic bacteria. Such a membrane protein complex comprises a number of subunits and cofactors. Without being bound by theory it is noted that when light is absorbed by a “reaction center” in a photosystem, a series of electron transfer reactions is initiated, leading to the reduction of a terminal acceptor. Known natural occurring photosystems include: Type I photosystem (e.g. photosystem I (P700) in chloroplasts and in green-sulphur bacteria) and Type II photosystem (e.g. photosystem II (P680) in chloroplasts and in non-sulphur purple bacteria). Each photosystem can be identified by the wavelength of light to which it is most reactive (700 and 680 nanometers, respectively for PSI and PSII in chloroplasts), and the type of terminal electron acceptor. Type I photosystems use ferredoxin-like iron-sulfur cluster proteins as terminal electron acceptors, while type II photosystems shuttle electrons to a quinone terminal electron acceptor. In some embodiments an electrode of the invention is capable of generating photochemical currents when exposed to light in the visible range.

In some embodiments, said photosystem complex or photo-catalytic element is derived from a natural source.

In other embodiments, a photosystem complex or photo-catalytic element is an isolated natural photosystem complex. In some further embodiments, said photosystem complex or photo-catalytic element is selected from photosystem I (PSI) complex, photosystem II complex and bacterial RC. In other embodiments, a photosystem complex or photo-catalytic element is a photosystem I (PSI) complex.

In further embodiments, photosystem complexes (or photo-catalytic elements) in the matrix are directly associated with a noble metal nano-particle. Direct association of said nano-particle and photosystem complexes (or photo-catalytic elements) may be achieved by any type of bond association such as for example a complexed bond, an electrostatic bond, a hybrid bond, a salt bond, a hydrogen bond and so forth.

Noble metal nano-particles, as used herein, include any noble metal nano-particles that are resistant to corrosion, oxidation and any type of tarnishing.

In other embodiments, said noble metal nano-particles in the matrix are each selected from ruthenium, rhodium, palladium, silver, osmium, iridium, platinum, gold and any combination thereof.

In other embodiments, at least one dimension of a noble metal nano-particle employed by the invention may range from about 2 nm to 150 nm. In some embodiments an electrode of the invention comprises at least one connecting group associated with at least one of (i) at least one nano-particle; (ii) at least one photo-catalytic element and (iii) conductive surface. In further embodiments an electrode of the invention comprises at least two connecting groups being the same or different.

In further embodiments, at least one of the one or more connecting groups is an electropolymerized oligomer.

The term “electropolymerized oligomer” is meant to encompass an oligomer produced by electropolymerization processes of at least one electropolymerizable monomer. An electropolymerized oligomer may comprise 2, 3, 4, 5, 6, 7, 8, 9, 10 electropolymerized monomer units. In some embodiments, an electropolymerizable monomer forming electropolymerized oligomer is selected from thioaniline, thiophenol, 2-amino-thiophenol, 3-amino-thiophenol, 4-amino-thiophenol, thiopyrrol, thiofurane, thiophene and any combinations thereof.

In other embodiments, said electropolymerized oligomer comprises at least two anchoring groups which may be the same or different and are each independently chemically associated with at least one matrix component (i.e. (i) at least one nano-particle and (ii) at least one photo-catalytic element) and/or to (iii) conductive surface. Said anchoring groups of an electropolymerized oligomer may be any group capable of associating to an NP though either through chemical bound(s) or by sorption association. In one embodiment said anchoring group is selected from S—, —NH₂ and —CO₂⁻.

In other embodiments, electropolymerized oligomer comprises one or more optionally substituted aromatic or heteroaromatic moieties.

In further embodiments, a connecting group in a composite matrix of an electrode of the invention is a group of the formula (I):

Z₁-L-Z₂ (I)

wherein each of the Z₁ and Z₂, are the same or different, is independently a bond or a moiety chemically associated with at least one of (i) at least one nano-particle of the composite (ii) at least one photo-catalytic element and (iii) conductive surface; and

L is a linker group comprising at least one electropolymerized monomer or oligomer thereof.

In some embodiments, L comprises one or more optionally substituted aromatic or heteroaromatic moieties.

In some embodiments, a connecting group connecting NPs to one another may be the same or different than a composite connecting group connecting NP to photo-catalytic element, or may be the same or different than a composite connecting group connecting phtocatalytic elements to one another.

In some embodiments, the connecting group connecting at least one noble metal nano-particle to at least one photo-catalytic element of said composite matrix is a group of the formula (II):

Z₃-L₁-Z₄ (II)

wherein each of the Z₃ and Z₄, are the same or different, is independently a bond or a moiety chemically associated with at least one of (i) at least one nano-particle of the composite and (ii) at least one photo-catalytic element; and

L₁ is a linker group comprising at least one electropolymerized monomer or oligomer thereof.

In other embodiments, the connecting group connecting said matrix composite to said conductive surface is a group of the formula (III):

Z₅-L₂-Z₆ (III)

wherein each of the Z₅ and Z₆, are the same or different, is independently a bond or a moiety chemically associated with at least one of (i) at least one nano-particle of the composite matrix, (ii) at least one photo-catalytic element and (iii) said conductive surface; and

L₂ is a linker group comprising at least one electropolymerized monomer or oligomer thereof.

In some embodiments, L₁ and L₂ may be the same or different and are independently comprise one or more optionally substituted aromatic or heteroaromatic moieties. In other embodiments, Z₃, Z₄, Z₅ and Z₆ may be the same or different.

In further embodiments of the invention, an electropolymerized monomer is selected from thioaniline, thiophenol, amino-thiophenol, thiopyrrol and any combination thereof.

In other embodiments, said matrix further comprises at least one electron acceptor group. In some embodiments said electron acceptor group is connected to said matrix composite of an electrode of the invention via a connecting group having a formula (VIII):

Z₁₁-L₇-Z₁₂ (VIII)

wherein each of the Z₁₁ and Z₁₂, are the same or different, is independently a bond or a moiety chemically associated with at least one of (i) at least one nano-particle of the composite, (ii) at least one photo-catalytic element and (iii) electron acceptor group; and

L₇ is a linker group comprising at least one electropolymerized monomer or oligomer thereof.

In some embodiments, an electron acceptor group is selected from ferredoxin, ferredoxin and any mixtures thereof.

In a further embodiment, an electrode of the invention further comprising at least one compound capable of mediating the electron transfer of said at least one photo-catalytic element. Such electron mediating compounds are chosen in accordance with the selected photo-catalytic element of the electrode. Non-limiting example of such compounds suitable for electron mediation via the surrounding environment of said electrode (for example in the surrounding buffer) is 2-hydroxy methyl 6-methoxy-1,4-benzoquinone, when the photo-catalytic element is PSII. 2-hydroxy methyl 6-methoxy-1,4-benzoquinone mediates the electron transfer of the PSII by entering the Q_{B} reducing site of the protein (replacing the naturally present, insoluble PQ9 quinone), becoming reduced and further donating the electrons. Another non-limiting example of an electron mediating compound is phenazine methosulfate, PMS.

In other aspects the invention provides a photovoltaic cell comprising an electrode of the invention.

In some other aspects the invention provides a device comprising a photo-sensitive electrode of the invention or a photovoltaic cell of the invention.

In another aspect, the invention provides a process of preparing a photo-sensitive electrode comprising:
contacting an electrode having a conductive surface and carrying a layer of electropolymerizable group having the general formula (IV):

Z₇-L₃ (IV)
wherein Z₇ is a bond or a moiety that is chemically associated with the conductive surface; and L₃ is a linker group comprising at least one electropolymerized monomer or oligomer thereof;
contacting the layered conductive surface with:
   (i) at least one noble metal nano-particle being chemically associated with at least one electropolymerizable group having the general formula (V):

Z₈-L₄ (V)
wherein Z₈ is a bond or a moiety that is chemically associated with the nano-particle; and L₄ is a linker group comprising at least one electropolymerized monomer or oligomer thereof; and
(ii) at least one photo-catalytic element being chemically associated with at least one electropolymerizable group having the general formula (VI):

Z₉-L₅ (VI)
wherein Z₉ is a bond or a moiety that is chemically associated with the photo-conductive element; and L₅ is a linker group comprising at least one electropolymerized monomer or oligomer thereof;
wherein Z₇, Z₈ and Z₉ may be the same or different, and L₃, L₄ and L₅ may be the same or different
electropolymerizing the electroploymerizable groups to obtain an electrode comprising a conductive surface connected to a composite matrix.

In some embodiments, a photo-sensitive electrode prepared by a process of the invention is an electrode comprising a conductive surface connected to a composite matrix; comprises: (i) noble metal nano-particles, (ii) photo-catalytic elements and (iii) connecting groups linking matrix components to one another and linking the matrix to the conductive surface; wherein said matrix being capable of transferring electrons from or to said surface upon exposure to light.

The term “chemically associated” is meant to encompass any type of chemical connection which may be a chemical bond or a sorption association between e.g. an anchoring group of a connecting group and a NP, an anchoring group and of a connecting group and a photosystem complex, an anchoring group of a connecting group and a conductive surface. The terms “bind”, “bond”, “bound” or “chemical bond” or any of their lingual derivatives refer to any form of establishing a substantially stable connection between different components (such as for example a NP and/or the conductive surface of an electrode of the invention) and an anchoring moiety of a connecting group. A bond may include, for example, a single, double or triple covalent bond, complex bond, electrostatic bond, Van-Der-Waals bond, hydrogen bond, ionic bond, π-interactions, donor-acceptor interactions or any combination thereof.

When referring to the term “sorb” or “sorbed” or any of their lingual derivatives it should be understood to encompass the occlusion of a moiety of a connecting group by means of absorption and/or adsorption and a component of a matrix and/or conductive surface of an electrode of the invention.

In some embodiments of a process of the invention, each of L₁, L₂ and L₃ independently of the other comprises one or more optionally substituted aromatic or heteroaromatic moieties.

In other embodiments of a process of the invention, L₁, L₂ and L₃ are each independently an electropolymerized monomer selected from thioaniline, thiophenol, amino-thiophenol, thiopyrrolor any combinations thereof.

In one embodiment Z₁ of a connecting group is chemically associated with a noble metal NP while Z₂ is chemically associated with a photo-catalytic element. In another embodiment Z₁ of a connecting group is chemically associated with a noble metal NP while Z₂ is chemically associated with the conductive surface of the electrode. In a further embodiment Z₁ of a connecting group is chemically associated with a photosystem complex while Z₂ is chemically associated with a conductive surface of the electrode. In one embodiment Z₁ of a connecting group is chemically associated with a noble metal NP while Z₂ is chemically associated with another a noble metal NP. In one embodiment Z₁ of a connecting group is chemically associated with a photo-catalytic element while Z₂ is chemically associated with another photo-catalytic element.

The term “optionally substituted aromatic or heteroaromatic moieties” should be understood to encompass an optionally substituted 5-12 membered aromatic or heteroaromatic ring systems. In one embodiment said ring systems is an optionally substituted fused aromatic or heteroaromatic ring systems. In another embodiment said ring system comprises at least two optionally substituted 5-12 membered aromatic or heteroaromatic moieties bonded to each other via at least one chemical bond (for example a single, double or triple bond). In yet another embodiment said ring system comprises at least two optionally substituted 5-12 membered aromatic or heteroaromatic moieties bonded to each other via at least one spacer moiety (for example —NH—, —O—, —S—, —NR— etc). In a further embodiment said ring system comprises at least two optionally substituted 5-12 membered aromatic or heteroaromatic moieties connected via π-π interaction. Optional substitution on an aromatic or heteroaromatic moieties include at least one of —NH₂, —NHR, —NR₂, —OH, —OR, —SH, —SR, wherein R is a C₁-C₁₂ alkyl or any other electron releasing group (including halo, phenyl, amine, hydroxyl, O⁻, etc.), substituted at any position of the aromatic or heteroaromatic moiety. Non limiting list of aromatic or heteroaromatic optionally substituted moieties include: phenylene, aniline, phenolynene, pyrrolynene, furynene, thiophenylene, benzofurylene, indolynene.

In one embodiment an electropolymerizable monomer of an electropolymerized oligomer of a connecting group is p-thioaniline. In another embodiment of the invention a connecting group of formula (I) is oligothianiline having 2, 3, 4, 5, 6, 7, 8, 9, 10 p-thioaniline (4-amino-thiophenol) monomer units electropolymerized to form a matrix defined above. In another embodiment said oligothioaniline is a group of formula (X):

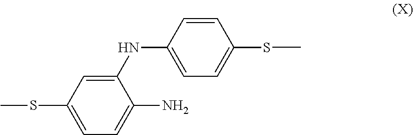

wherein each of the S moieties are independently chemically sorbed to two noble metal NP/two photosystem complex (which may be complexed with noble metal NP)/a noble metal NP and a photo-catalytic element (which may be complexed with noble metal NP)/a noble metal NP and conductive surface/a photo-catalytic element (which may be complexed with noble metal NP) and a conductive surface, all as defined herein above. Each NP may be further connected through the same or different connecting groups to other NPs/photosystem complex (which may be complexed with noble metal NP).

The formation of a layer of at least one electropolymerizable group on a conductive surface can be performed by reacting the conductive surface with a solution comprising a precursor of an electropolymerizable group. In one embodiment said precursor is p-aminothiophenol, forming a thioaniline layer on a conductive surface. In one embodiment of a process of the invention the photo-catalytic element are chemically bonded or sorbed with at least one thioaniline group. In a further embodiment of a process of the invention the noble nano-particles are chemically bonded or sorbed with at least one thioaniline group.

Electropolymerization processes used in the process of the invention relate to the 10-100 repetitive cyclic voltammetry scans of a mixture of a plurality of photo-catalytic elements having chemically bonded or sorbed thereon at least one electropolymerizable group, a plurality of noble metal NPs having chemically bonded or sorbed thereon the same or different at least one electropolymerizable group and a conductive surface having chemically bonded or sorbed thereon at least one electropolymerizable group. In one embodiment 10 repetitive cyclic voltammetry scans are performed. In another embodiment 20 repetitive cyclic voltammetry scans are performed. In yet a further embodiment 40 repetitive cyclic voltammetry scans are performed. In another embodiment 60 repetitive cyclic voltammetry scans are performed. In a further embodiment 80 repetitive cyclic voltammetry scans are performed. In one embodiment 100 repetitive cyclic voltammetry scans are performed. In another embodiment the mixture of said nano-particles and said layered surface has a pH of between about 7 to about 10.

In yet further embodiments of a process of the invention, said electropolymerizing step is performed in the presence of at least one electron acceptor molecule chemically associated with at least one electropolymerizable group having the general formula (VII):

Z₁₀-L₆ (VII)

wherein Z₁₀ is a bond or a moiety that is chemically associated with the electron acceptor molecule; and L₆ is a linker group comprising at least one electropolymerized monomer or oligomer thereof.

In some embodiments of the invention, Z, Z₁-Z₁₂ are the same or different and are each independently a bond or a moiety chemically associated with at least one matrix component of an electrode of the invention.

In other embodiments of the invention and L, L₁-L₇ are the same or different and are each a linker group comprising at least one electropolymerized monomer or oligomer thereof.

In some other embodiments of a process of the invention, an electron acceptor molecule is selected from ferredoxin, flavodoxin and any combination thereof.

### BRIEF DESCRIPTION OF THE DRAWINGS

In order to understand the invention and to see how it may be carried out in practice, embodiments will now be described, by way of non-limiting example only, with reference to the accompanying drawings, in which:

FIGS. 1A-1B is a schematic presentation of a modification of the PSI with polymerizable thioaniline functionality (FIG. 1A). FIG. 1B illustrates a bis-aniline-crosslinked PSI monolayer on a Au electrode.

FIGS. 2A-2B is a schematic presentation of a bis-aniline-crosslinked Pt NPs-“plugged-in” Pt nanoclusters/PSI composite on a Au electrode. FIG. 2B illustrates a non directed bis-aniline-crosslinked Pt NPs/PSI composite on a Au electrode.

FIG. 3 is a schematic presentation of a bis-aniline-crosslinked Ferredoxin/Pt NPs-“plugged-in” Pt nanoclusters/PSI composite on a Au electrode.

FIG. 4 is a photocurrent action spectrum of a bis-aniline-crosslinked PSI monolayer on a Au electrode. Measurement was performed in a phosphate buffer solution (0.1 M, pH=7.4) that included ascorbic acid, 40 mM, and dichlorophenolindophenol (DCPIP), 56 μM.

FIG. 5 is a photocurrent action spectra obtained by: (a) A bis-aniline-crosslinked Pt NPs-“plugged-in” Pt nanoclusters/PSI composite on a Au electrode; (b) A non directed bis-aniline-crosslinked Pt NPs/PSI composite on a Au electrode. Measurements were performed in a phosphate buffer solution (0.1 M, pH=7.4) that included ascorbic acid, 40 mM, and DCPIP, 56 μM.

FIG. 6 is a photocurrent intensities generated by the bis-aniline-crosslinked Pt NPs-“plugged-in” Pt nanoclusters/PSI composite-modified Au electrode generated by a variable number of electrochemical deposition cycles. Measurements were performed in a phosphate buffer solution (0.1 M, pH=7.4) that included ascorbic acid, 40 mM, and DCPIP, 56 μM.

FIG. 7 is a potential-dependent photocurrents, measured at λ=437 nm, generated by the bis-aniline-relay/Pt-NP/PSI 60 cycles-composite, in the presence of phosphate buffer solution (0.1 M, pH=7.4) that included ascorbic acid, 40 mM, and DCPIP, 56 μM.

FIG. 8 is a photocurrent action spectra obtained by: (a) A bis-aniline-crosslinked Ferredoxin/Pt NPs-“plugged-in” Pt nanoclusters/PSI composite on a Au electrode; (b) A bis-aniline-crosslinked Pt NPs-“plugged-in” Pt nanoclusters/PSI composite on a Au electrode. Measurements were performed in a phosphate buffer solution (0.1 M, pH=7.4) that included ascorbic acid, 40 mM, and DCPIP, 56 μM.

FIG. 9 is a TEM image of thioaniline-modified Pt-NPs.

FIGS. 10A-10B show a linear sweep voltammograms (FIG. 10A) corresponding to the redox active F_{AB} site, performed at different scan rates: (a) 100; (b) 200; (c) 300; (d) 400, and (e) 500 mV s⁻¹. FIG. 10B is a linear dependence of the current value, at E=−0.5 V vs. SCE, on the scan rate.

FIGS. 11A-11B illustrate photo-bio fuel cells employing bio-photoactive anodes. In FIG. 11A, the anode comprises a PSII protein—Pt nano-cluster linked to a 1,4 benzenedithiol monolayer-modified Au surface. FIG. 11B, illustrates an anode wherein the PSII is covalently linked to a propionic acid monolayer-modified Au surface. The anodes were integrated into bio-fuel cells employing Pt cathodes that facilitate the reduction of protons to hydrogen.

FIG. 12 depicts the photocurrent action spectra associated with the electrode configurations discussed in FIGS. 11A and 11B.

FIG. 13 demonstrates the effect of the addition of 2-hydroxy methyl 6-methoxy-1,4-benzoquinone, on the performance of the aligned PSII/Pt-modified electrode of FIG. 11A.

FIG. 14 depicts a photobiofuel cell configuration that contains an anode composed of the aligned PSII/Pt matrix cluster (and uses phenazine methosulfate, PMS, (2) as an electron mediating compound), and a Pt cathode on which the reduction of Fe(CN)₆³⁻ to Fe(CN)₆⁴⁻ takes place.

FIG. 15 shows the light-induced activation of the photobiofuel cell in FIG. 14.

FIG. 16 depicts a photobiofuel cell composed of the aligned PSII/Pt nanocluster matrix anode (employing compound (4) as an electron mediator), and an O₂-reducing enzymatic cathode.

FIGS. 17A-17B shows the discharge (polarization) curve (FIG. 17A) and the power density output (FIG. 17B) of the cell of the electrode of the photobiofuel cell in FIG. 16.

FIG. 18 demonstrates the light-induced activation of the photobiofuel cell in FIG. 16.

FIG. 19 demonstrates the repeated light-induced activation of the photobiofuel cell in FIG. 16 following 10 minutes of heating the BOD cathode to 70° C.

FIG. 20 illustrates a system of the invention comprising one electrode having an electropolymerized bis-aniline-crosslinked PSII/Pt NPs matrix connected to an Au conductive surface and another electrode of the invention having an electropolymerized bis-aniline-crosslinked BOD enzyme/Pt NPs matrix connected to an Au conductive surface.

### DETAILED DESCRIPTION OF EMBODIMENTS

PSI Functionalized Photo-Electrodes

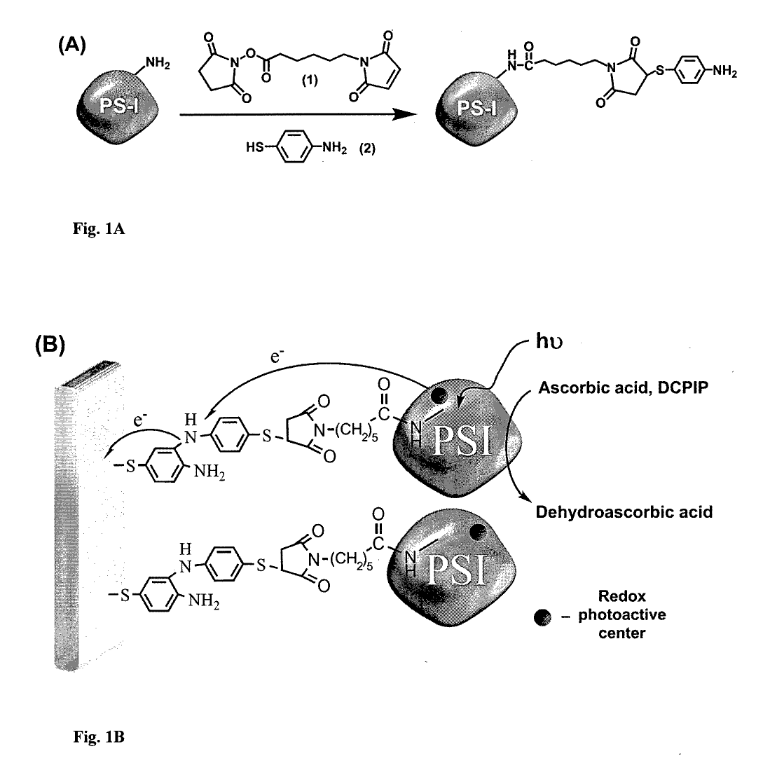

Functionalization of PSI was achieved with thioaniline electropolymerizable units as shown in FIG. 1(A). The lysine residues of the protein were reacted with the bifunctional reagent [N-c-Maleimidocaproyloxy]sulfosuccinimide ester, (1), and the resulting maleimide sites were reacted with p-aminothiophenol (2), to yield the thioaniline-functionalized PSI. After the modification of the protein with thioaniline no change to the spectrum of the PSI was observed. The modified PSI was, then, electropolymerized onto a thioaniline-functionalized Au electrode to yield a bis-aniline-crosslinked PSI layer on the electrode, FIG. 1(B). As the protein composite insulates the electrode, substantially complete monolayer coverage can be expected. Complementary microgravimetric quartz-crystal-microbalance (QCM) measurements, in which the modified PSI was electropolymerized onto a thioaniline-functionalized Au/quartz piezoelectric crystal indicated a frequency change of 50 Hz, that translates to a surface coverage of 2.7×10¹³ mole·cm⁻². The projection of PSI is ca. 330 nm², [40] and thus, a random, densely packed PSI monolayer exhibits a coverage of 3.2×10⁻¹³ mol·cm⁻². Thus, the experimental data suggest that the coverage of PSI on the electrode corresponds to ca. 85% of a random densely-packed monolayer. The resulting PSI monolayer-functionalized electrodes were, then, illuminated in the presence of ascorbic acid as an electron donor and dichlorophenolindophenol (DCPIP) as a mediator.

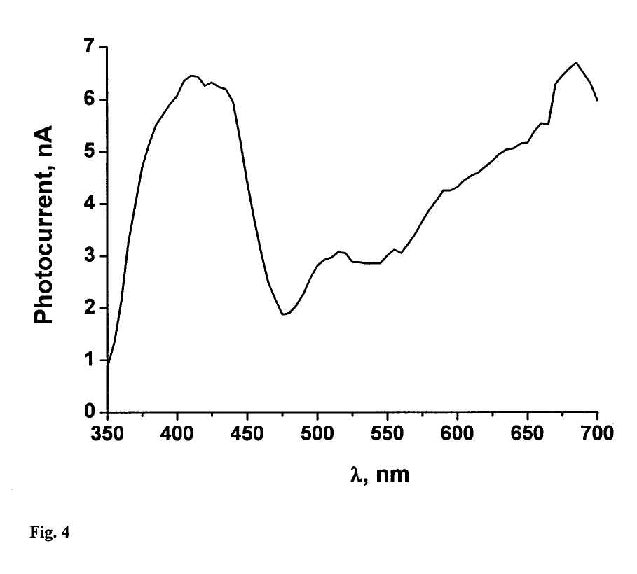

FIG. 4 shows the resulting photocurrent action spectrum, that overlaps the absorbance characteristics of PSI. The resulting photocurrent is, thus, obtained by an electron transfer from the excited chromophore to the electrode followed by the reduction of the oxidized chromophore by the electron donors. The resulting photocurrent is, however, minute in its intensity, ca. 6 nA (26nA/cm²) at λ=420 nm. These low photocurrents may be attributed to the following reasons: (i) A low coverage of PSI in a monolayer configuration on the electrode, (ii) Different orientations of the photoactive center of the PSI in respect to the electrode, and (iii) Inefficient charge-injection to the electrode in the randomly oriented configuration that results in the decay of the photoexcited state, or the recombination of the electron transfer species generated in the PSI.

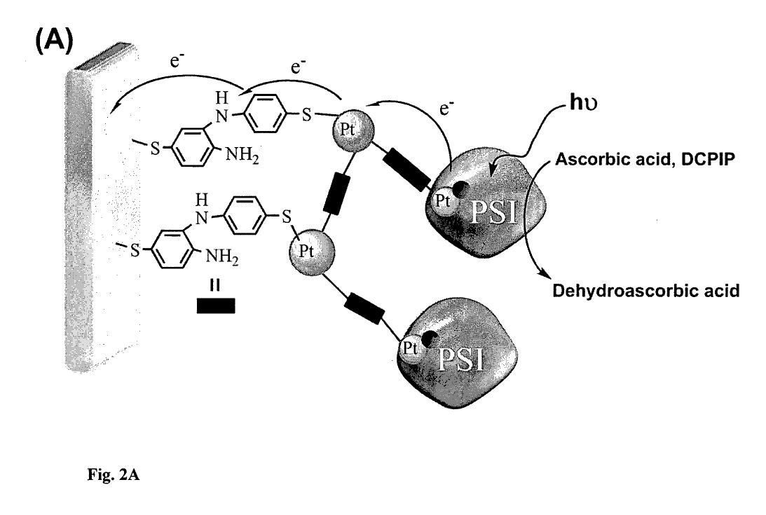

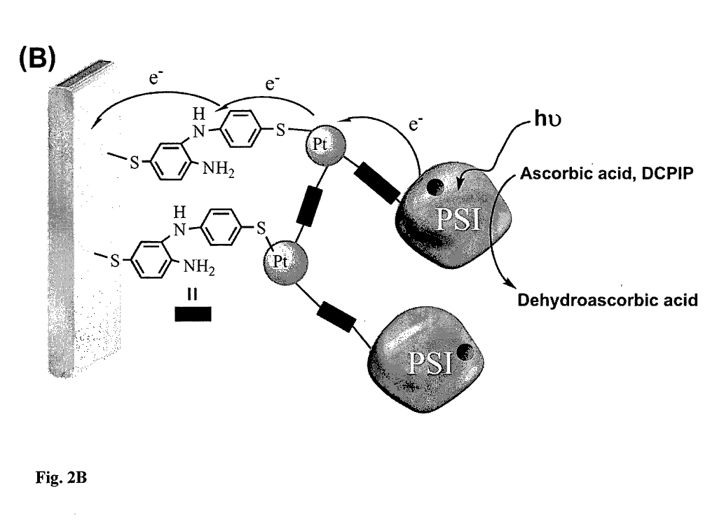

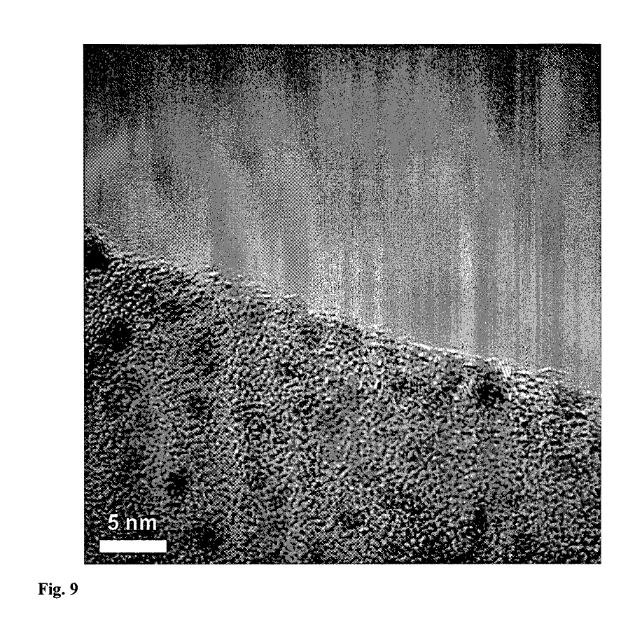

The unique charge transport properties of the bis-aniline-crosslinked metal nano-particles/protein composites was implemented in order to design a Pt NPs/PSI hybrid system. Therefore, a Pt salt solution was irradiated in the presence of PSI and the electron donors, resulting in the formation of Pt⁰ nano-clusters electrically attached to the F_{AB} site (the last acceptor unit in the electron transfer chain starting at the P-700, the photoactive center of the PSI protein). In fact, together with Pt nano-clusters plugged into the PSI, Pt NPs were also formed in the solution (see FIG. 9). Thus, the modification of the Pt-modified PSI, and the accompanying Pt NPs, with thioanline yielded an active mixture for electropolymerizing the Pt NPs/PSI composite on the electrode. Accordingly, a K₂PtCl₆ solution was reduced with PSI in the presence of ascorbic acid and DCPIP, a process that plugged in Pt nanoclusters into the PSI and yielded free Pt NPs in the solution. Treatment of the system with thioanline, followed by the electropolymerization of the mixture on a thioaniline-functionalized Au electrode resulted in the formation of the NPs/PSI composite on the electrode, FIG. 2(A). The Pt NPs in the solution and the “plugged-in” Pt nano-clusters introduce several important functionalities to the system: (i) The electropolymerization of the mixture results in a conductive three-dimensional composite that allows the increase in the content of the PSI on the electrode by facilitating three-dimensional electropolymerization of the PSI. (ii) The three dimensional structure of the Pt NPs/PSI composite, trapped the photo-ejected electrons and thereby enhance the charge separation, leading to enhanced photocurrent yields.

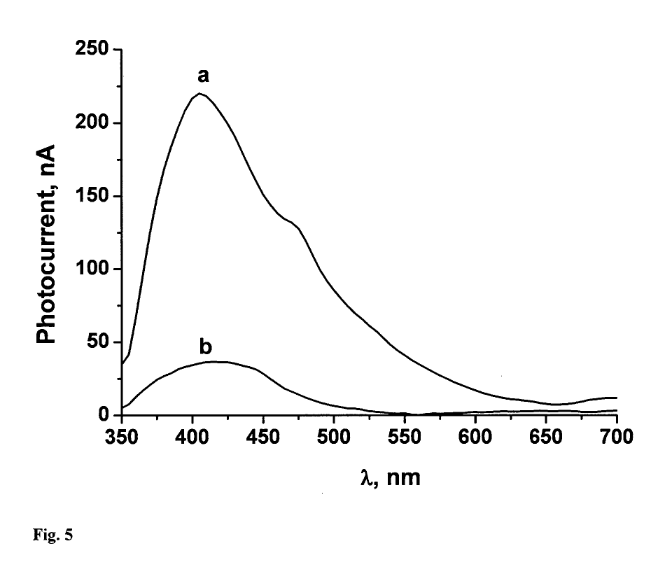

FIG. 5, curve (a), shows the photocurrent action spectrum generated by the Pt NPs-“plugged-in” Pt nanoclusters/PSI composite. The resulting photocurrent at λ=420 nm, ca. 220 nA (1 μA cm⁻²), is ca. 35-fold higher than the photocurrent generated by the PSI monolayer associated with the electrode. Also, QCM measurements indicated that the mass associated with the composite increased by ca. 3-fold (to a value of 1.4×10⁻⁶ gr cm⁻²), while the photocurrents demonstrated a 35-fold increase, implying a significant improvement in the efficiency of the electron transfer in the Pt NPs-“plugged-in” Pt nano-clusters/PSI composite. The photocurrent at λ=680 nm, observed for the monolayer structure is, however, almost depleted. Without being bound by theory it is noted that the Pt-NPs/Pt nano-clusters quench effectively this electronic state to a non-charge-separable state that does not lead to the generation of photocurrent.

The Pt NPs-“plugged-in” Pt nano-clusters/PSI composite in FIG. 2(A) was compared to the non-directed Pt NPs/PSI composite that lacked the “plugged in” metallic core, FIG. 2(B). In this system, the thioaniline-functionalized PSI was electropolymerized with thioaniline-modified Pt NPs on the electrode surface to yield a non-directed bis-aniline crosslinked Pt-NPs/PSI composite on the electrode (the content of PSI on both the directed and non-directed systems was similar as observed by the coulometric analyses of the redox centers of PSI in the two systems (vide infra). FIG. 5, curve (b) shows the photocurrent action spectrum of the non-directed bis-aniline-crosslinked Pt NPs/PSI electrode. The photocurrent intensity at λ=420 nm generated by the non-directed system is only 16% of the photocurrent generated by the Pt NPs/Pt nanoclusters “plugged-in” PSI system. This result highlights the significance of the “plugged-in” Pt nanoclusters in reducing the electron transfer distances from the F_{AB} site to adjacent Pt NPs, thus enhancing charge-separation. While in the non-directed bis-aniline Pt-NPs/PSI composite the photocenters of PSI are randomly positioned in respect to the Pt NPs, leading to a less efficient charge separation, the implanted Pt-nanoclusters orient the photocenters in respect to the Pt-NPs available in the composite, thus leading to improved charge separation. It should be noted, that in a further control experiment, Pt NPs were formed by irradiating a PtCl₆²⁻ solution under similar conditions to the preparation of the “plugged-in”-Pt nanoclusters PSI composite, but in the absence of the PSI. These Pt NPs were, then, reacted with thioaniline and polymerized with a thioaniline-tethered (as shown in FIG. 1(A)) PSI. The photocurrent action spectrum associated with this electrode exhibited similar response to the one presented in FIG. 5, curve (b). This later control experiment demonstrates that the photochemically-induced incorporation of the Pt nanoclusters in the PSI structure is essential to yield the high photocurrent values. The quantum yield for the generation of the photocurrent at λ=420 nm was ca 2.6%. (lamp intensity at 437 nm 1.13 mW).

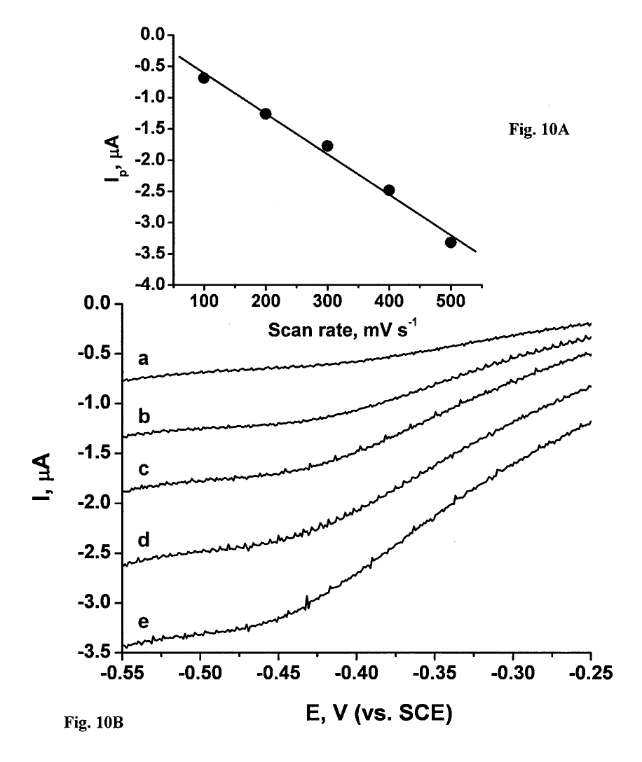

The Pt NPs/Pt nanoclusters “plugged-in” PSI composite associated with the electrode was then characterized. The composite reveals a voltammetric response at −0.45 V vs. SCE (see FIGS. 10A-10B) that is associated with the iron-sulfur clusters (F_{AB}) of PSI. The peak current of the voltammetric wave revealed a linear dependence with the scan-rate, consistent with a surface confined protein. The coulometric analysis of the voltammetric wave, and complementary QCM measurements, indicated an average surface coverage of 1.4×10⁻¹² mole cm⁻² which translates to 4 random densely-packed layers of electropolymerized PSI. Thus, the loading of PSI was 4-fold higher in the Pt NPs/PSI composite as compared to the monolayer configuration.

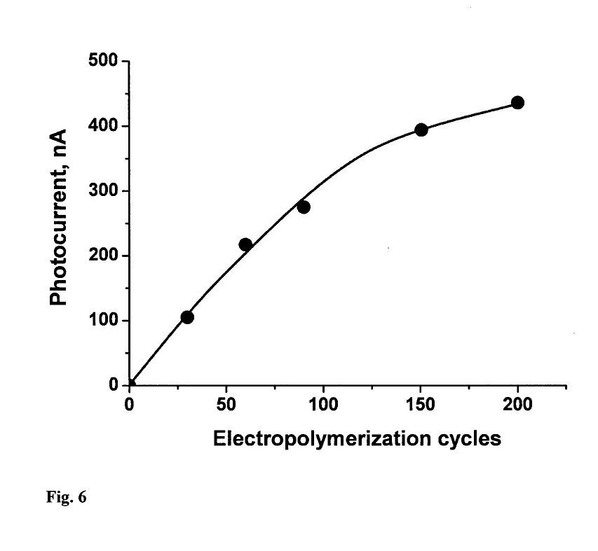

The content of the photoactive PSI on the electrode, and thus, the resulting photocurrents may be controlled by the number of electropolymerization cycles applied to synthesize the composite. FIG. 6 shows the intensities of the photocurrents at λ=420 nm generated by PSI matrices which were formed by variable numbers of electropolymerization cycles. As the number of electropolymerization cycles increases the photocurrents are intensified, and they reach a saturation current of ca. 450 nA (ca. 2 μA cm⁻²) after ca. 200 electropolymerization cycles. The leveling-off of the photocurrents is attributed to the fact that upon increasing the content of the PSI in the composite, an increasing number of protein “insulating spots” are formed, and therefore perturb the conductivity paths in the composite, resulting in the lack of further growth of the film.

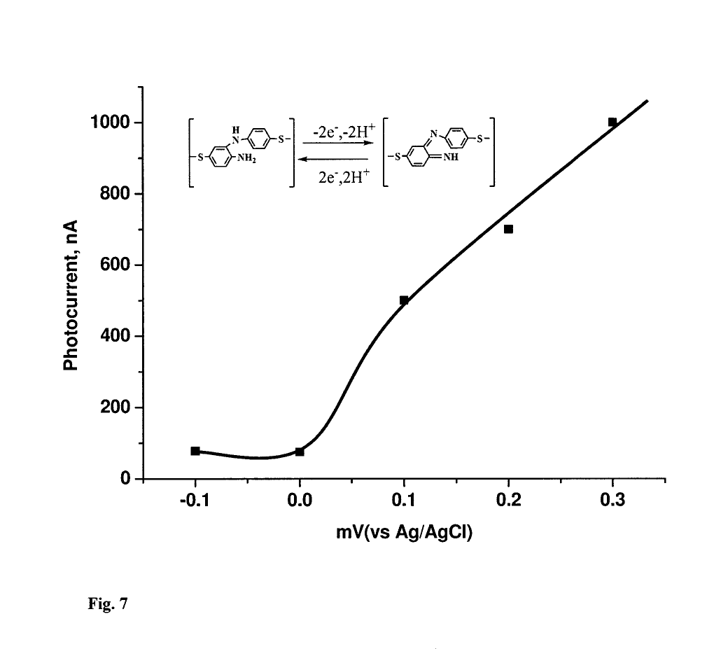

The open-circuit potential of the electrode modified with the bis-aniline-crosslinked PSI/Pt NPs composite corresponded to ca. 50 mV vs. Ag/AgCl. The fact that the bis-aniline crosslinking units reveal a quasi-reversible redox wave at ca. 50 mV, implies that the bridging units consist of an equilibrium composed of the reduced bis-aniline state and the oxidized quinoid state, (see Eq. 1 in FIG. 7). Accordingly, the effect of external potential bias on the resulting photocurrent was studied. As could be seen from FIG. 7, a decrease in the photocurrent is observed at E<0.0 V vs. Ag/AgCl (ca. 10 fold decrease as compared to the photocurrent at E=0.3 V vs. Ag/AgCl). These results suggest that the bis-aniline bridges participate in the charge transport from the PSI to the electrode and affect the resulting photocurrents. At positive potentials, the bridging units exist in the quinoid electron acceptor state. The direct trapping of electrons from the photo-excited PSI or mediating the electron transfer of electrons trapped by the Pt nano-clusters, facilitate charge separation and lead to the effective charge transport of the electrons to the electrode. At E<0.0 V vs. Ag/AgCl, the binding units exist in their reduced state that lacks electron acceptor properties. As a result, the bridging units do not trap the electrons generated by the PSI, and substantially lower photocurrent values are observed.

In order to further increase the resulting photocurrents biomaterial additives or conductive nano-scale units were implemented. In nature, the iron-sulfur protein, ferredoxin, mediates the electron transfer from PSI to NAD(P)⁺ reductase. The primary trapping of the electrons by the ferredoxin units induces charge-separation in the photosynthetic apparatus, leading to efficient light-to-chemical energy conversion.

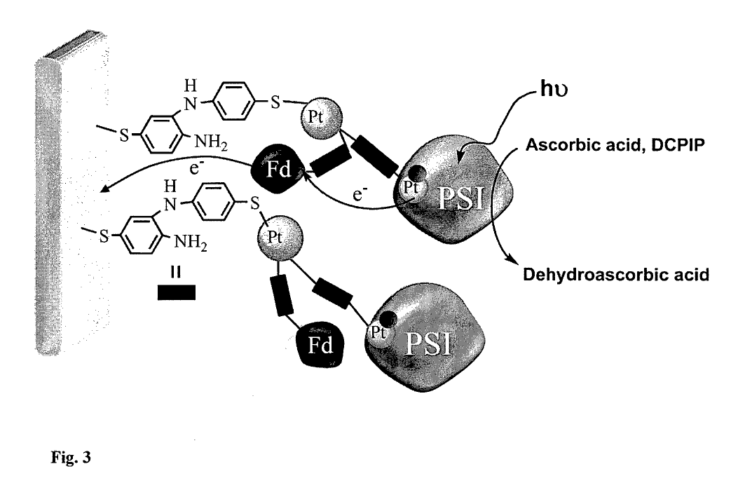

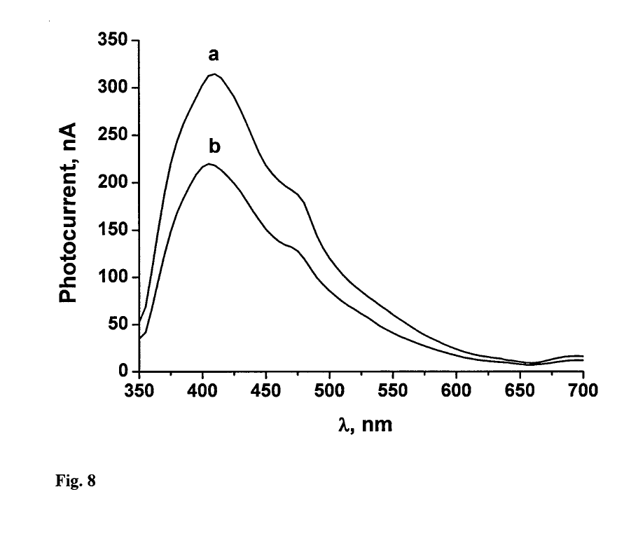

The charge separation in the Pt-NPs/Pt nano-clusters “plugged-in” PSI composite is affected by the charge trapping and transport of electrons by the Pt NPs. The introduction of high surface-area conductive nano-objects into the PSI composite could, then, further enhance charge-separation and increase the photocurrent yields. Accordingly, ferrodoxin was functionalized with thioaniline units by the primary modification of the lysine residues with (1) and the covalent linkage of thioaniline to the maleimide residues. Both the thioaniline-modified Pt NPs and Pt-nano-cluster “plugged-in” PSI were electropolymerized in the presence of the thioaniline-functionalized ferredoxin (Fd), to yield the Pt NPs/Fd/PSI crosslinked composite, FIG. 3. FIG. 8, curve (a), shows the photocurrent action spectrum generated by the Pt NPs/Fd/PSI composite (synthesized by 60 electropolymerization cycles), in comparison to the Pt NP/PSI composite that lacked the Fd units, FIG. 8, curve (b). A ca. 40% increase (ca 1.38 2.2×10⁻⁶ gr/cm²) in the photocurrent intensity is observed in the presence of Fd, which is attributed to the improved charge separation in the Fd-containing composite. The quantum yield for the generation of the photocurrent at λ=420 nm is ca 3.8%.

PSII Functionalized Electrodes

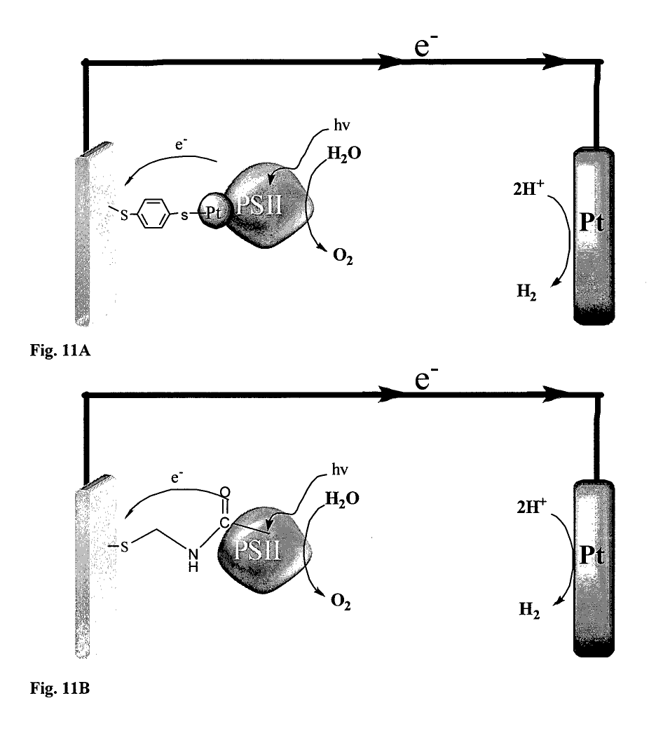

FIG. 11 illustrates photobiofuel cells employing bio-photoactive anodes which are based on monolayers of PSII were constructed. In configuration shown in FIG. 11A, the PSII protein was initially irradiated in the presence of a Pt salt, which led to the reduction of the salt and the formation of a Pt nano-cluster (Pt NC) at the Q_{B} reducing site of the protein. The resulting PSII/Pt nano-cluster hybrid was, then, linked to a 1,4 benzenedithiol monolayer-modified Au surface. In this configuration, the redox-active site of the PSII is sterically aligned towards the electrode and is wired through the Pt NC (which is anticipated to yield an improved electrical communication between the photoactive protein and the Au support). In the second configuration shown in FIG. 11B, the PSII was covalently linked to a propionic acid monolayer-modified Au electrode through the lysine amino acids existing at the protein's backbone. In this configuration the Q_{B} site is not aligned towards the electrode, which is expected to yield a worse electrical communication and, thus, a decreased cell performance. The anodes were integrated into biofuel cells employing Pt cathodes that facilitate the reduction of protons to hydrogen. Accordingly, the anodic reaction involves the oxidation of water (the fuel), with the generated protons diffusing away to the cathode where they become reduced to yield hydrogen.

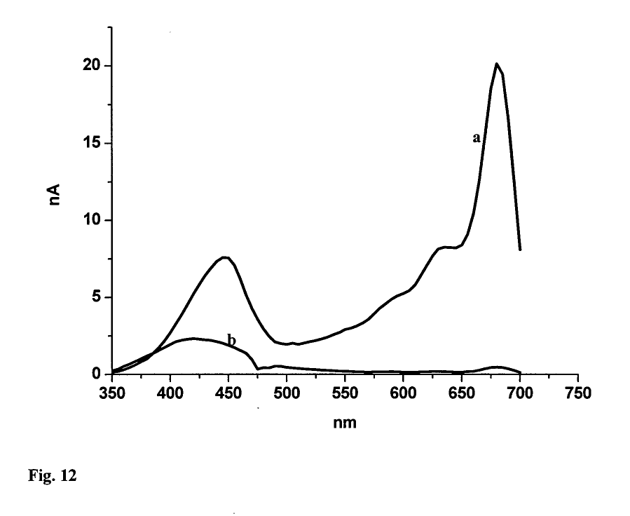

FIG. 12 depicts the photocurrent action spectra associated with the configurations discussed in FIGS. 11A and 11B. The photocurrent spectra match the absorption characteristics associated with a solubilized PSII, indicating that indeed the photocurrent originates from the protein activity. As expected, the aligned PSII/Pt NC exhibits an improved photo-response (higher photocurrents) due to the enhanced electrical communication between the protein and the electrode provided by the alignment and the presence of the Pt nano-relay unit.

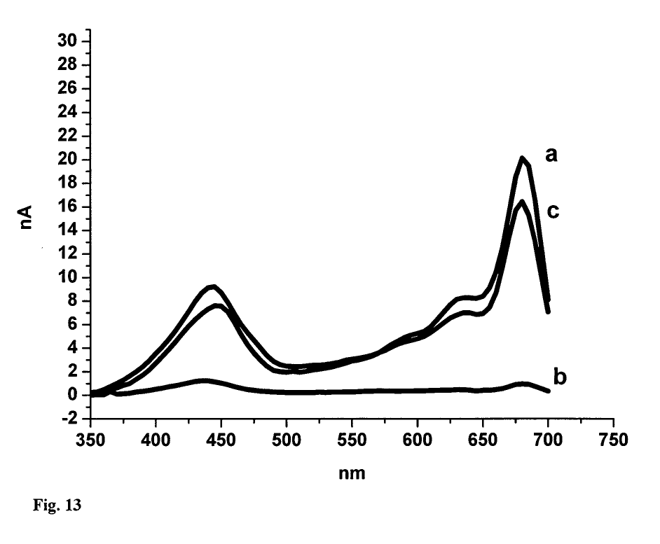

FIG. 13 demonstrates the effect of the addition of 2-hydroxy methyl 6-methoxy-1,4-benzoquinone, (3), on the performance of the aligned PSII/Pt NC monolayer-modified electrode. Compound (3) mediates the electron transfer of the PSII by entering the Q_{B} reducing site of the protein (replacing the naturally present, insoluble PQ9 quinone), becoming reduced and further donating the electrons. As expected, upon the addition of compound (3) to the phosphate buffer (0.1 M, pH=7.4) electrolyte, relatively higher photocurrents were achieved (curve a). Upon the removal of (3) from the electrolyte (using pure buffer), the photocurrents decreased (curve b), and upon the re-introduction of (3) to the system, the currents raised again (curve c). This experiment highlights the importance of specific redox-active molecules for improving the charge transfer in the PSII photoelectrochemical configurations.

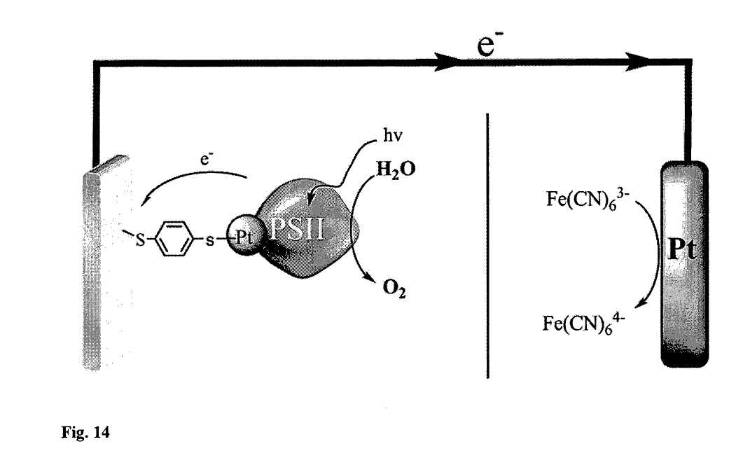

FIG. 14 depicts a photobiofuel cell configuration that contains an anode composed of the aligned PSII/Pt NC (and uses phenazine methosulfate, PMS, (4) as an electron mediating compound), and a Pt cathode on which the reduction of Fe(CN)₆³⁻ to Fe(CN)₆⁴⁻ takes place. According to the two half cell potentials governed by the mediators, an open circuit voltage of ca. 450 mV is expected for the cell. The cell employs a membrane separating the anode and cathode compartments.

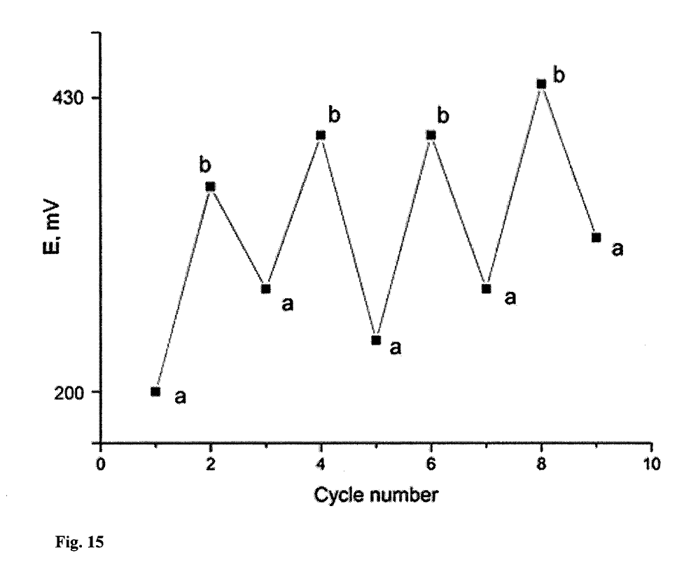

FIG. 15 shows the light-induced activation of the photobiofuel cell in FIG. 14. The potential is measured upon the cyclic illumination and darkening of the cell. A load of 1 MΩ is used for the discharge.

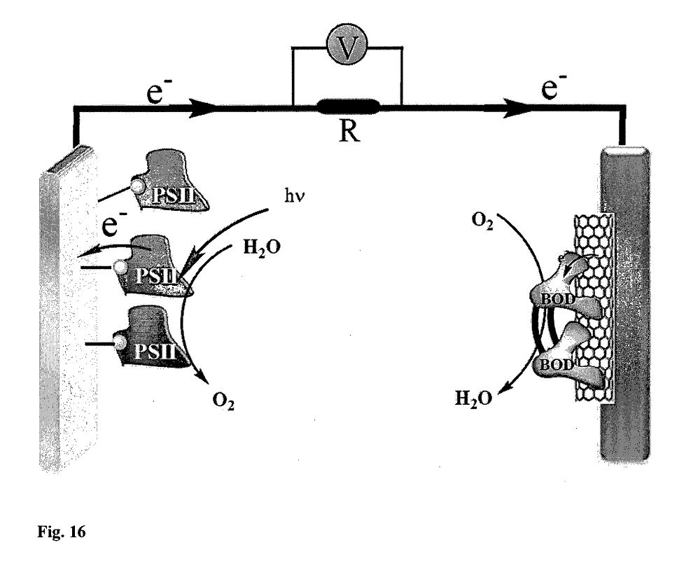

FIG. 16 depicts a photobiofuel cell composed of the aligned PSII/Pt NC anode (employing compound (4) as an electron mediator), and an O₂-reducing enzymatic cathode. The cathode is constructed from carbon nanotubes (CNTs) adsorbed on a glassy carbon support, on which a bilirubin oxidase (BOD) enzyme was adsorbed and crosslinked using bis(sulfosuccinimidyl) suberate. The cell is chemically balanced between the O₂ and the H₂O reagent/products. The cell employs a membrane separating the anode and cathode compartments.

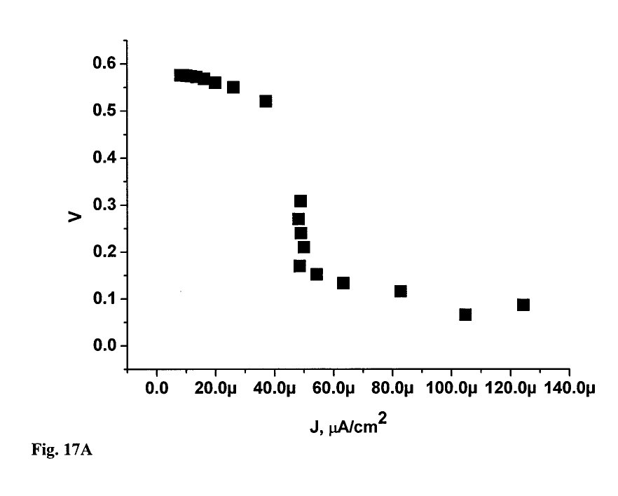

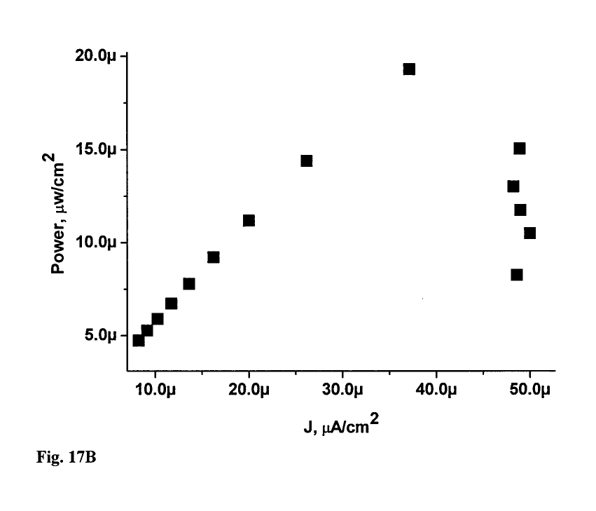

FIG. 17 shows the discharge (polarization) curve (A) and the power density output (B) of the cell of the electrode of the photobiofuel cell in FIG. 16. The measurements were performed using different constant external loads (resistances). They were carried out under illumination and in the presence of air.

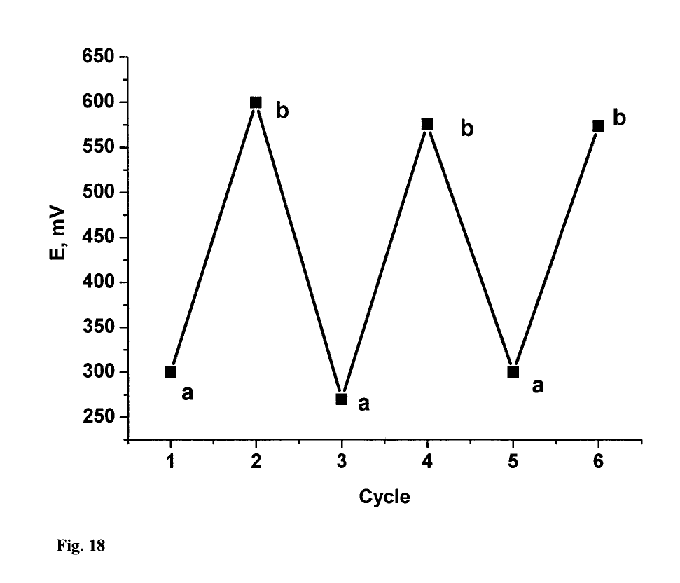

FIG. 18 demonstrates the light-induced activation of the photobiofuel cell in FIG. 16. The potential is measured upon the cyclic illumination and darkening of the cell. A load of 1 MΩ is used for the discharge.

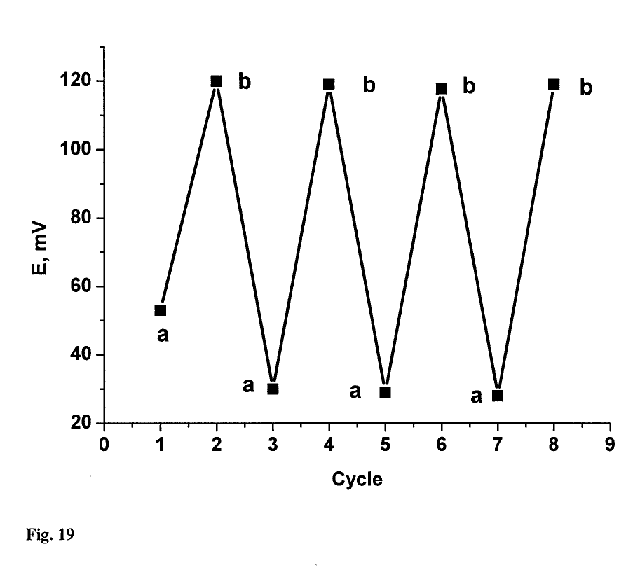

FIG. 19 is the repetition of the results of the light-induced activation of the photobiofuel cell in FIG. 16, but following 10 minutes of heating the BOD cathode to 70° C. in order to denaturate the enzyme. As expected, the cell performance was deteriorated (lower voltages were measured), indicating the contribution of the BOD cathode to the operation of the cell.

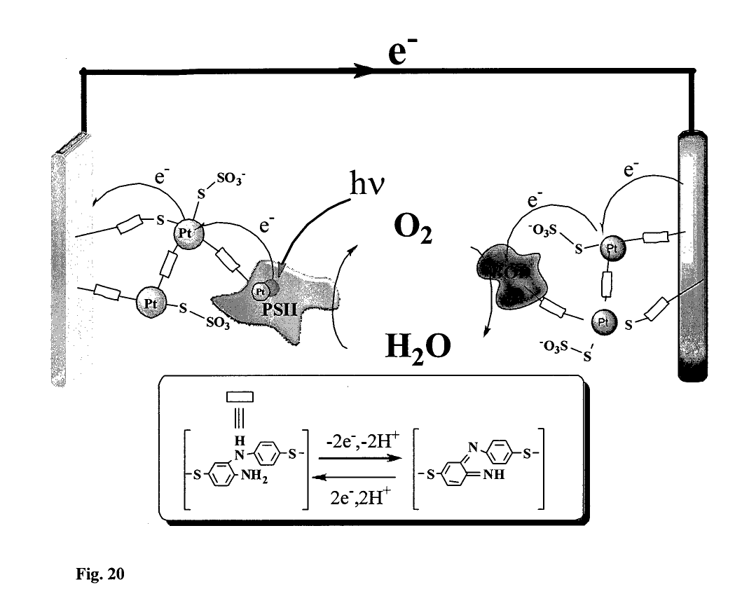

FIG. 20 illustrates a system of the invention comprising one electrode having an electropolymerized bis-aniline-crosslinked PSII/Pt NPs matrix connected to an Au conductive surface (thioaniline-functionalized Pt NPs and thioaniline-modified Pt NC/PSII are co-electropolymerized onto a thioaniline-modified Au surface). The illustrated system further comprises another electrode of the invention having an electropolymerized bis-aniline-crosslinked BOD enzyme/Pt NPs matrix connected to an Au conductive surface (a BOD enzyme is modified with thioaniline units and is co-electropolymerized with thioaniline-functionalized Pt NPs onto a thioanline-modified Au electrode). The use of these hybrid matrices is expected to both increase the content of both PSII and BOD on the surfaces and exploit the high conductivity of the Pt NPs for achieving an effective charge transfer, which will hopefully increase the photobiofuel cell performance.

### EXAMPLES

### Example 1

### Functionalization of the PSI and Ferrodoxin with Thioaniline Units

PSI, was isolated as described in Ref 42. 0.85 mg chlorophyll mL⁻¹, was dissolved in 0.01 M HEPES buffer (3 mL, pH 7.2) that included N-(maleimidocaproyloxy)sulfosuccinimide ester (sulfo-EMCS, obtained from PIERCE), 17 μg mL⁻¹. The resulting solution was stirred for 40 min and was, then, reacted with p-aminothiophenol in ethanol, 57 μg mL⁻¹. Similarly, ferrodoxin, 24 mg mL⁻¹, was dissolved in 0.01 M HEPES buffer (5 mL, pH 7.2) that included sulfo-EMCS, 1.8 mg mL⁻¹. The resulting solution was stirred for 40 minutes and was, then, reacted with p-aminothiophenol in ethanol, 0.5 mg mL⁻¹.

### Example 2

### Implantation of Polymerizable Pt Nano-Clusters into the Redox Active Center of the PSI

An N-[Tri(hydroxymethyl)methyl]glycine (Tricine) buffer solution (10 mM, pH=7.9) that included the PSI, 0.34 mg chlorophyll mL⁻¹, K₂PtCl₆, 110 μM, 2,6-dichlorophenolindophenol (DCPIP), 34 and ascorbic acid, 19 mM, was irradiated for 40 minutes at λ>400 nm using a Xe lamp (P=100 W). The resulting Pt NPs/Pt nanoclusters “plugged-in” PSI solution was reacted for 5 h with an ethanolic solution that included p-aminothiophenol, 8 mM, to modify the Pt clusters with the polymerizable thioaniline units.

### Example 3

### Modification of the Electrodes

Clean Au slides were reacted with p-aminothiophenol, 10 mM, in ethanol for 12 h. The thioaniline-functionalized slides were, then, subjected to electropolymerization in the presence of the thioaniline-modified PSI, 120 μg chlorophyll mL⁻¹, and in the presence or the absence of thioaniline-modified ferrodoxin, 2 μg mL⁻¹. The electropolymerization was carried out in the presence of the photogenerated Pt nano-particles solution using a fixed number of repetitive cyclic voltammetry scans, ranging between −0.1 V and +1.1 V vs. saturated calomel electrode (SCE), at a scan rate of 100 mVs⁻¹.

Instrumentation

Electropolymerization of the electrodes was carried out using an Autolab electrochemical system (ECO Chemie, The Netherlands) driven by the GPES software. A SCE and a carbon rod (d=5 mm) were used as the reference and counter electrodes, respectively. Photoelectrochemical experiments were performed using a home-built photoelectrochemical system that included a Xe lamp (Oriel, model 6258, P=300 W), a monochromator (Oriel, model 74000, 2 nm resolution), and a chopper (Oriel, model 76994). The electrical output from the cell was sampled by a lock-in amplifier (Stanford Research model SR 830 DSP). The shutter chopping frequency was controlled by a Stanford Research pulse/delay generator, model DE535. The photogenerated currents were measured between the modified Au working electrode and the carbon counter electrode.

QCM measurements were performed using a home-built instrument linked to a frequency analyzer (Fluke) using Au-quartz crystals (AT-cut 10 MHz).

1-27. (canceled)

28. An electrode comprising a conductive surface connected to a composite matrix; said matrix comprising: at least one noble metal nano-particle, at least one photo-catalytic element and at least one connecting group; said composite matrix being capable of transferring electrons from or to said conductive surface upon exposure to light.

29. An electrode comprising a conductive surface connected to a composite matrix; said matrix comprising: noble metal nanoparticles, photocatalytic elements and connecting groups linking matrix components to one another and linking the matrix to the conductive surface; said matrix being capable of transferring electrons from or to said surface upon exposure to light.

30. The electrode of claim 28, wherein said photo-catalytic element is derived from a natural source.

31. The electrode of claim 28, wherein the photo-catalytic element is an isolated natural photosystem complex selected from photo-system I (PSI) complex, photo-system II (PSII) complex and bacterial RC.

32. The electrode of claim 28, wherein at least one photo-catalytic element is directly associated with at least one noble metal nano-particle.

33. The electrode of claim 28, wherein said at least one noble metal nano-particle is selected from ruthenium, rhodium, palladium, silver, osmium, iridium, platinum, gold and any combination thereof.

34. The electrode of claim 28, comprising at least one connecting group associated with at least one of (i) at least one nano-particle; (ii) at least one photo-catalytic element and (iii) conductive surface.

35. The electrode of claim 28, comprising at least two connecting groups being the same or different.

36. The electrode of claim 28, wherein at least one connecting group is an electropolymerized oligomer comprising at least two anchoring groups which may be the same or different and are each independently chemically associated with at least one of (i) at least one nano-particle; (ii) at least one photo-catalytic element and (iii) conductive surface.

37. The electrode of claim 28, wherein said at least one connecting group is a group of the formula (I):
Z₁-L-Z₂ (I)
wherein each of the Z₁ and Z₂, are the same or different, is independently a bond or a moiety chemically associated with at least one of (i) at least one nano-particle; (ii) at least one photo-catalytic element and (iii) conductive surfacenano-particlephoto-catalytic; and
L is a linker group comprising at least one electropolymerized monomer or oligomer thereof.

38. The electrode of claim 37, wherein electropolymerized monomer is selected from thioaniline, thiophenol, amino-thiophenol, thiopyrrol and any combination thereof.

39. The electrode of claim 28, wherein the connecting group connecting at least one noble metal nano-particle to at least one photo-catalytic element of said composite matrix is a group of the formula (II):
Z₃-L₁-Z₄ (II)
wherein each of the Z₃ and Z₄, are the same or different, is independently a bond or a moiety chemically associated with at least one of (i) at least one nano-particle of the composite matrix and (ii) at least one photo-catalytic element and
L₁ is a linker group comprising at least one electropolymerized monomer or oligomer thereof.

40. The electrode of claim 28, wherein the connecting group connecting said matrix composite to said conductive surface is a group of the formula (III):
Z₅-L₂-Z₆ (III)
wherein each of the Z₅ and Z₆, are the same or different, is independently a bond or a moiety chemically associated with at least one of (i) at least one nano-particle of the composite matrix, (ii) at least one photo-catalytic element and (iii) said conductive surface; and
L₂ is a linker group comprising at least one electropolymerized monomer or oligomer thereof.

41. The electrode of claim 28, wherein said composite matrix further comprises at least one electron acceptor group.

42. The electrode of claim 41, wherein the electron acceptor group is selected from ferredoxin, ferredoxin and any mixtures thereof.

43. The electrode of claim 28, further comprising at least one compound capable of mediating the electron transfer of said at least one photo-catalytic element.

44. A photovoltaic cell comprising an electrode of claim 28.

45. A process of preparing a photo-sensitive electrode comprising:
contacting an electrode having a conductive surface and carrying a layer of electropolymerizable group having the general formula (IV):
Z₇-L₃ (IV)
wherein Z₇ is a bond or a moiety that is chemically associated with the conductive surface; and L₃ is a linker group comprising at least one electropolymerized monomer or oligomer thereof;
contacting the layered conductive surface with:
(i) at least one noble metal nano-particle being chemically associated with at least one electropolymerizable group having the general formula (V):
Z₈-L₄ (V)
wherein Z₈ is a bond or a moiety that is chemically associated with the nano-particle; and L₄ is a linker group comprising at least one electropolymerized monomer or oligomer thereof; and
(ii) at least one photo-catalytic element being chemically associated with at least one electropolymerizable group having the general formula (VI):
Z₉-L₅ (VI)
wherein Z₉ is a bond or a moiety that is chemically associated with the photo-catalytic element; and L₅ is a linker group comprising at least one electropolymerized monomer or oligomer thereof;
wherein Z₇, Z₈ and Z₉ may be the same or different, and L₃, L₄ and L₅ may be the same or different
electropolymerizing the electroploymerizable groups to obtain an electrode comprising a conductive surface connected to a composite matrix.
